(19) United States
(12) Patent Application Publication
(10) Pub. No.: US 2025/0031583 A1
(43) Pub. Date: Jan. 23, 2025

(54) HIGH-TEMPERATURE SUPERCONDUCTOR

(71) Applicants: Hyundai Motor Company, Seoul (KR); Kia Corporation, Seoul (KR); Seoul National University R&DB Foundation, Seoul (KR)

(72) Inventors: Hoo Dam Lee, Seoul (KR); Tae Gyu Lee, Seoul (KR); Kyung Sik Choi, Seoul (KR); Hyung Kwan Jang, Uijeongbu-si (KR); Byung Ho Min, Suwon-si (KR); Jun Hyeok Choi, Suwon-Si (KR); Yeahan Sur, Suwon-Si (KR); Sukho Kim, Hwaseong-si (KR); Kee Hoon Kim, Seoul (KR); Jungwoo Lee, Seoul (KR)

(21) Appl. No.: 18/522,794

(22) Filed: Nov. 29, 2023

(30) Foreign Application Priority Data
Jul. 21, 2023 (KR) 10-2023-0095435

(51) Int. Cl. H10N 60/01; H10N 60/85

(52) U.S. Cl. CPC H10N 60/0268; H10N 60/857

(57) ABSTRACT

Provided is a ReBCO-based high-temperature superconductor composition and a method of preparing the same comprising substituting a part of Gd with Ho, wherein the ReBCO-based high-temperature superconductor is represented by ReBa₂Cu₃O_{7-δ}, in which Re comprises or consists of Gd and Ho. The superconductor may improve the critical current density without a change in the critical temperature.

### CROSS-REFERENCE TO RELATED APPLICATION

This application is based on and claims priority under 35 U.S.C. 119 to Korean Patent Application No. 10-2023-0095435, filed on Jul. 21, 2023, in the Korean Intellectual Property Office, the disclosure of which is herein incorporated by reference in its entirety.

### BACKGROUND

### 1. Technical Field

The present disclosure relates to a high-temperature superconductor and, more specifically, to a high-temperature superconductor.

### 2. Discussion of Background

In 1911, Heike Kamerlingh Onnes at the Netherlands' Leiden university discovered, while conducting an experiment to measure the electrical resistance of mercury, that the electric resistance suddenly disappeared at an absolute temperature of 4.2 K (−268.8° C.). Subsequent to this discovery, low-temperature superconductors, such as NbTi and SnTi, began to be used in applications requiring strong magnetic fields.

In 1987, a high-temperature superconductor was discovered by Johannes Bednorz and Karl Muller of Switzerland. Since then, research has been actively conducted to improve the critical temperatures and critical current densities of high-temperature superconductors.

The main compositions of high-temperature superconductors are Bismuth Strontium Calcium Copper Oxide (BSCCO) and Rare-earth element Barium Copper Oxide (ReBCO). In ReBCO, Re denotes a rare earth element, which is typically Y or Gd. These compositions are chemically unstable (or non-stoichiometric compounds) in terms of the oxygen content in Cu-Oxide. Thus the control of an oxygen atmosphere is important during the preparation and use thereof.

The chemical compositions of BSCCO are divided into Bi₂Sr₂CuO₆₊ₓ, Bi₂Sr₂CuO₈₊ₓ, and Bi₂Sr₂CuO₁₀₊ₓ, wherein the higher the oxygen content in Cu-Oxide, the higher the critical temperature (Tc). These BSCCO substances are under research and development to replace for NbTi and SnTi through wire preparation by an extrusion process. However, price problems need to be overcome, since Ag is used for texturing control to increase the critical resistance of BSCCO.

The chemical composition of ReBCO is ReBa₂Cu₃O_{7-δ}, which has a lower critical temperature than BSCCO but can have a high critical current. However, in many cases, ReBCO is generally manufactured into wires through a thin film process since, unlike BSCCO, the critical current of ReBCO rapidly decreases according to the texture.

The descriptions in this background section are intended merely to aid in the understanding of the background of the present disclosure, and are not intended to as an admission that the present disclosure falls within the purview of the related art already known to those or ordinary skill in the art to which this technology belongs.

### SUMMARY

The following summary presents a simplified summary of certain features. The summary is not an extensive overview and is not intended to identify key or critical elements.

The applicant conducted research directed to improving the critical current density of GdBCO, which is a ReBCO-based alloy, and contemplated that the substitution of a rare earth element with a specific element might improve the critical current density without a change in the critical temperature. The applicant therefore conducted research on the substitution of a rare earth element.

The present disclosure provides a high-temperature superconductor composition capable of improving the critical current density without a change in the critical temperature by substituting a part of Gd, constituting a ReBCO-based superconductor, with Ho. Critical current density (J_C) may represent the maximum amount of electrical current a super conductor can carry at a specific temperature and a specific magnetic field. The critical current density may be the maximum amount of current that can flow through a unit area (e.g., cm²) of a superconductor.

The technical objectives pursued in the present disclosure may not be limited to the above-mentioned technical subjects, and other technical subjects which are not mentioned may be clearly understood, through the following descriptions, by those skilled in the art to which the present disclosure pertains.

A rare-earth barium copper oxide (ReBCO)-based high-temperature superconductor composition may be represented by ReBa₂Cu₃O₇₋₆, wherein Re is Gd and Ho.

The high-temperature superconductor composition may be represented by HoₓGd₁₋ₓBa₂Cu₃O_{7-δ}, wherein x satisfies 0<x<1 and δ satisfies δ<7.

In the high-temperature superconductor composition, x may satisfy 0.4≤x≤0.6.

In a (Gd,Ho)BCO-based high-temperature superconductor composition, a part of Gd may be substituted with Ho.

In the high-temperature superconductor composition, about 40-60% of a mole percentage of Gd before substitution may be substituted with Ho.

A method for preparing a (Gd,Ho)BCO-based superconductor composition may comprise: preparing separately a Gd oxide powder, a Ba oxide powder, a Cu oxide powder, and a Ho oxide powder; a mixing step comprising mixing the prepared Gd oxide powder, Ba oxide powder, and Cu oxide powder according to a stoichiometry to prepare a mixed powder wherein a part of the Gd oxide powder is substituted with the Ho oxide powder; a molding step comprising molding the prepared mixture powder into a molded body; a first heating step comprising adjusting an amount of carbon (C) in the molded body; a second heating step comprising synthesizing the molded body into a (Gd,Ho)BCO-based molded body; a third heating step comprising growing crystal grains of the molded body; and an oxygen heating step comprising adjusting an amount of oxygen (O) in the molded body.

In the mixing step, 40-60% of a mole percentage of Gd of the Gd oxide powder may be substituted with Ho of the Ho oxide powder.

In the molding step, the mixture powder may be press-molded.

In the molding step, the mixture powder may be press-molded at about 5-20 MPa.

The first heating step may comprise: heating the molded body at a heating rate of about 10° C./min or less; maintaining the molded body at about 880° C. for about 20 hours or longer; and cooling the molded body at a cooling rate of about 10° C./min or less.

The second heating step may comprise: heating the molded body at a heating rate of about 10° C./min or less; maintaining the molded body at about 900° C. for about 20 hours or longer; and cooling the molded body at a cooling rate of about 10° C./min or less.

The third heating step may comprise: heating the molded body at a heating rate of about 10° C./min or less; maintaining the molded body at about 925° C. for about 15 hours or longer; and cooling the molded body at a cooling rate of about 10° C./min or less.

In the oxygen heating step, the molded body may be heat-treated at about 500° C. for about 12 hours or longer in an oxygen atmosphere.

According to various examples of the present disclosure, the following advantages may be expected by substituting a part of Gd, constituting a ReBCO-based superconductor composition, with Ho.

First, the utilization of the superconductor composition as a wire material may increase the critical current density of the wire material when applied to a driving motor, consequently increasing the magnetic field of a superconductor coil (a race track) beyond that of a wire material at the level of a GdBCO-based superconductor, thereby improving or maximizing the output density.

Second, the utilization of the superconductor composition as a superconductor bulk magnet may increase the critical current density of the bulk magnet that is placed, thereby improving or maximizing the output density of a motor.

### BRIEF DESCRIPTION OF THE DRAWINGS

FIG. 1 depicts a schematic diagram showing the crystal structure of a high-temperature superconductor.

FIGS. 2A and 2B depict graphs showing a change in the crystal structure as a function of the addition of Ho.

FIG. 3 depicts a graph showing a change in magnetic susceptibility (M) as a function of the addition of Ho at 10 K.

FIG. 4 depicts a graph showing a change in critical current density (Je) as a function of the addition of Ho at 10 K by using Bean model.

FIG. 5 depicts a graph showing a change in magnetic susceptibility (M) as a function of the addition of Ho at 77 K.

FIG. 6 depicts a graph showing a change in critical current density (Je) as a function of the addition of Ho at 77 K by using Bean model.

FIG. 7 depicts a graph showing a change in critical current value (J_{c, self}) as a function of the addition of Ho at 10 K.

FIG. 8 depicts a graph showing a change in critical current value (J_{c, self}) as a function of the addition of Ho at 77 K.

FIG. 9 depicts a graph showing changes in critical current value (J_{c, self}) as a function of the type of rare earth element substituted for Gd and the additional amount thereof.

### DETAILED DESCRIPTION OF THE EXEMPLARY EMBODIMENTS

Hereinafter, examples disclosed in the present specification will be described in detail with reference to the accompanying drawings, and the same or similar elements are given the same and similar reference numerals, so duplicate descriptions thereof will be omitted.

In describing the various examples disclosed in the present specification, when the detailed description of the relevant known technology is determined to unnecessarily obscure the gist of the present disclosure, the detailed description may be omitted. Furthermore, the accompanying drawings are provided only for understanding of the examples disclosed in the present specification, and the technical spirit disclosed herein is not limited to the accompanying drawings, and it should be understood that all changes, equivalents, or substitutes thereof are included in the spirit and scope of the present disclosure.

Terms including an ordinal number such as “first”, “second”, or the like may be used to describe various elements, but the elements are not limited to the terms. The above terms are used only for the purpose of distinguishing one element from another element.

A singular expression may include a plural expression unless they are definitely different in a context.

As used herein, the expression “include” or “have” specify the existence of mentioned features, numbers, steps, operations, elements, components, or combinations thereof, but do not preclude the possible existence or addition of one or more other features, numbers, steps, operations, elements, components, or combinations thereof.

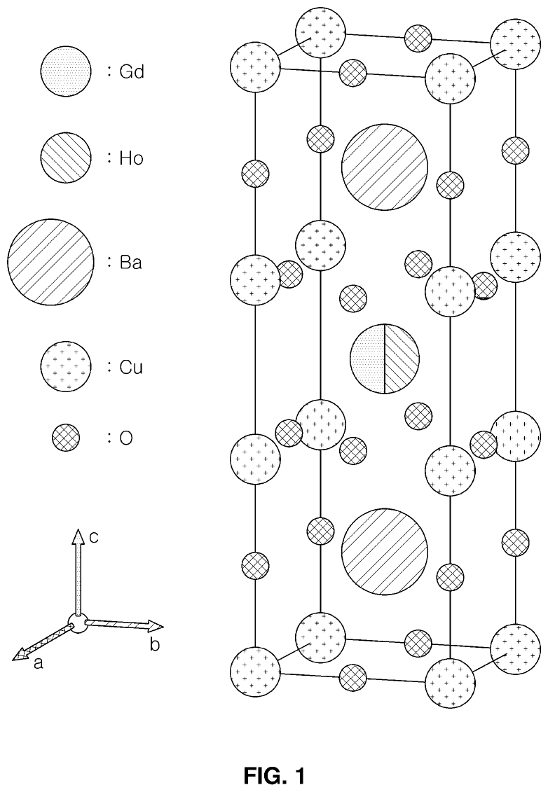

FIG. 1 depicts a schematic diagram showing the crystalline structure of a high-temperature superconductor.

As shown in FIG. 1, the high-temperature superconductor composition may be a ReBCO-based high-temperature superconductor, which is represented by ReBa₂Cu₃O_{7-δ}. In various examples, Re comprises or consists of Gd and Ho.

More specifically, the high-temperature superconductor composition according to an example of the present disclosure is a (Gd, Ho)BCO-based high-temperature superconductor composition, in which a part of Gd is substituted with Ho.

For example, the high-temperature superconductor may be represented by HoₓGd₁₋ₓBa₂Cu₃O_{7-δ}.

In one or more examples, x may satisfy 0<x<1 and δ may satisfy δ<7.

In particular, x may satisfy 0.4≤x≤0.6.

In one or more examples, the amount of Ho substituted may be 40-60% of the mole percentage of Gd before substitution. For example, when the content of Gd is 1 mol % before a part of Gd is substituted with Ho, the content of Gd after substitution may be 0.4-0.6 mol % and the content of Ho after substitution may be 0.4-0.6 mol %, since 40-60% of Gd is substituted with Ho.

In various examples, for a rare earth element to be substituted at the sites of Gd, an element of the Lanthanide group may be selected considering a similar ionic diameter to Gd and changes in the magnetic moment (pB/h) and the critical current density (A). As shown herein, substitution with Ho was confirmed to be able to significantly increase the critical current density.

Specifically, a part of Gd is substituted with Ho in the crystal structure of the unit lattice of the superconductor, wherein Ho³⁺ is substituted for Gd³⁺ in the unit lattice of HoₓGd₁₋ₓBa₂Cu₃O_{7-δ}.

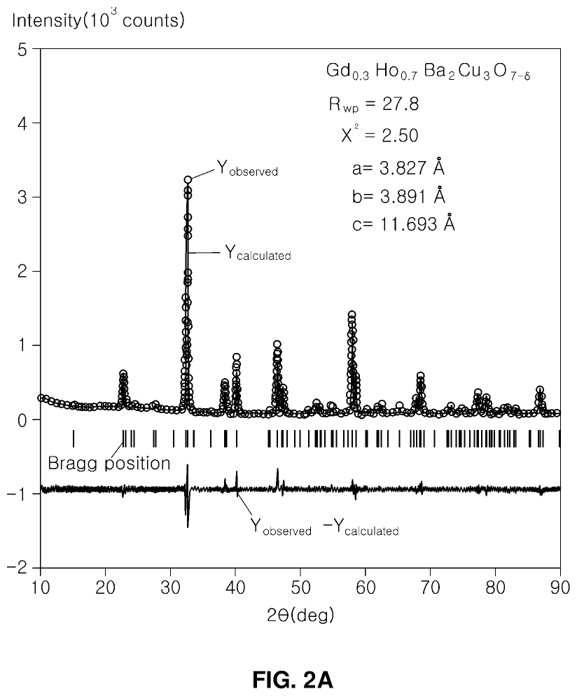

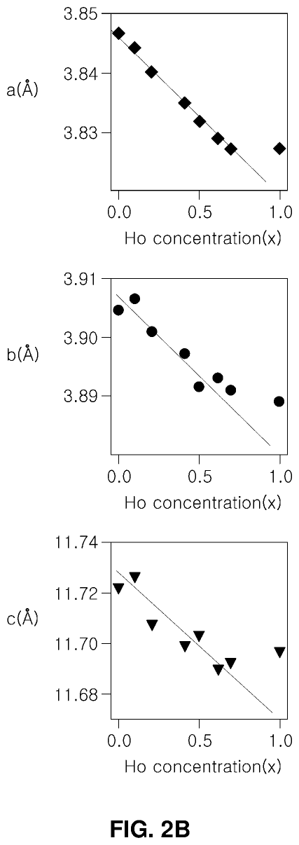

The date in FIGS. 2A and 2B support that such a substitution did not influence the crystal structure of the unit lattice or superconductivity of the HoₓGd₁₋ₓBa₂Cu₃O_{7-δ} substance.

FIGS. 2A and 2B depict graphs showing a change in the crystal structure depending on the addition of Ho, confirming through XRD analysis that the crystal structure was not changed even though a part of Gd is substituted with Ho in the crystal structure of the unit lattice of the superconductor composition.

Then, a method for preparing a high-temperature superconductor composition according to an embodiment of the present disclosure is described.

The method for preparing a high-temperature superconductor according to an embodiment of the present disclosure is a method for preparing a (Gd,Ho)BCO-based superconductor. The method comprises: a powder preparation step of separately preparing a Gd oxide powder, a Ba oxide powder, a Cu oxide powder, and a Ho oxide powder; a mixing step of mixing the prepared Gd oxide powder, Ba oxide powder, and Cu oxide powder according to the stoichiometry of a (Gd,Ho)BCO-based superconductor composition to prepare a mixed powder while substituting a part of the Gd oxide powder with the Ho oxide powder; a molding step of molding the prepared mixture powder into a molded body; a first heat treatment step of adjusting the content of carbon (C) in the molded body; a second heat treatment step of synthesizing the molded body into a (Gd,Ho)BCO-based molded body; a third heat treatment step of growing crystal grains of the molded body; and an oxygen heat treatment step of adjusting the content of oxygen (O) in the molded body.

In the powder preparation step, the Gd oxide powder, Ba oxide powder, Cu oxide powder, and Ho oxide powder are separately prepared.

The Gd oxide powder, Ba oxide powder, Cu oxide powder, and Ho oxide powder may be prepared in the forms of Gd₂O₃, BaCO₃, CuO, and Ho₂O₃, respectively.

In the mixing step, the amounts of Gd oxide powder, Ba oxide powder, Cu oxide powder, and Ho oxide powder mixed are determined according to the molar ratio of Gd, Ba, Cu, and Ho in order to prepare a high-temperature superconductor represented by HoₓGd₁₋ₓBa₂Cu₃O_{7-δ}. x may satisfy 0<x<1 and δ satisfies δ<7. In particular, x may satisfy 0.4≤x≤0.6.

For example, the respective amounts of Gd oxide powder, Ba oxide powder, Cu oxide powder, and Ho oxide powder mixed are determined such that the molar ratio of Gd, Ba, Cu, and Ho can be 0.5:2:3:0.5.

The molar ratio of Gd and Ho may be maintained at about 40-60%:about40-60%.

In the molding step, the mixture powder obtained by mixing the Gd oxide powder, Ba oxide powder, and Cu oxide powder with the Ho oxide powder by the mixing amounts determined according to the predetermined molar ratio is press-molded into a molded body with a predetermined shape.

In the molding step, the mixture powder may be pressed at about 5-20 MPa.

In the first heat treatment step, the heat treatment is performed to adjust the content of carbon (C) in the molded body.

To this end, the first heat treatment step includes: a first heating step of heating the molded body; a first maintaining step of maintaining the molded body at about 880° C. for about 20 hours or longer (but may be less than 50 hours); and a first cooling step of cooling the molded body.

Particularly, when the molded body is heated in the first heating step, a heating rate of about 10° C./min or less (but greater than 0° C./min) is desirably maintained to minimize the thermal impact of the molded body. The heating may be desirably performed at about 120° C./hr.

Similarly, when the molded body is cooled in the first cooling step, a cooling rate of about 10° C./min or less (but greater than 0° C./min) is desirably maintained to minimize the thermal impact of the molded body. The cooling may be desirably performed at about 120° C./hr.

In the first maintaining step, if the heat treatment is performed at a lower temperature for a shorter time than at the suggested temperature for the suggested time, which are the minimum conditions for adjusting the content of carbon (C) in the molded body, the heat treatment effect may not be sufficiently achieved. The heat treatment may be for controlling the carbon content within the molded body, and its effectiveness may be related to the carbon content.

In the second heat treatment step, the heat treatment is performed to ensure the high-temperature superconductor HoₓGd₁₋ₓBa₂Cu₃O_{7-δ}.

To this end, the second heat treatment step includes: a second heating step of heating the molded body; a second maintaining step of maintaining the molded body at about 900° C. for about 20 hours or longer (but may be less than 50 hours); and a second cooling step of cooling the molded body at a cooling rate of about 120° C./hr.

Particularly, when the molded body is heated and cooled in the second heating step and the second cooling step, the heating rate and the cooling rate may be maintained at about 10° C./min or less to minimize the thermal impact of the molded body. The heating and cooling each may be desirably performed at about 120° C./hr.

Similarly, in the second maintaining step, if the heat treatment is performed at a lower temperature for a shorter time than at the suggested temperature for the suggested time, which are the minimum conditions for ensuring the high-temperature superconductor HoₓGd₁₋ₓBa₂Cu₃O_{7-δ}, the heat treatment effect may not be sufficiently achieved. The second heat treatment may be the process of synthesizing the molded body into (Gd, Ho) BCO system, and its effectiveness may be related to the completion of the molding.

In the third heat treatment step, the heat treatment is performed to increase the crystal grain size and ensure stable crystallinity of HoₓGd₁₋ₓBa₂Cu₃O_{7-δ}.

To this end, the third heat treatment step includes: a third heating step of heating the molded body; a third maintaining step of maintaining the molded body at about 925° C. for about 15 hours or longer (but may be less than 50 hours); and a third cooling step of cooling the molded body.

Similarly, when the molded body is heated and cooled during the third heating step and the third cooling step, the heating rate and the cooling rate are desirably maintained at about 10° C./min or less to minimize the thermal impact of the molded body. The heating and cooling may each be performed at about 120° C./hr.

In the third maintaining step, if the heat treatment is performed at a lower temperature for a shorter time than at the suggested temperature for the suggested time, which are the minimum conditions for increasing the crystal grain size and ensuring stable crystallinity of the high-temperature superconductor HoₓGd₁₋ₓBa₂Cu₃O_{7-δ}, the heat treatment effects may not be sufficiently achieved. The third heat treatment process may be a phase aimed at increasing the crystalline size and ensuring stable crystallinity of the polymer, and the effects may be related thereto.

In the oxygen heat treatment step, the heat treatment is performed to stabilize the content of oxygen (O) in the molded body.

To this end, in the oxygen heat treatment step, the molded body may be heat-treated at about 500° C. for about 12 hours or longer (but may be less than 50 hours) in an oxygen atmosphere. For example, a superconductor, REBCO7-δ, may be associated with the oxygen atmosphere in which oxygen in the superconductor is unstable. Due to this characteristic, even when manufacturing the material, the oxygen concentration may not reach 7. To address this, heat treatment may be conducted in an oxygen atmosphere to ensure that the oxygen in the superconductor reaches 7.

Without being limited by theory, the reasons why in the crystal structure of the unit lattice of the high-temperature superconductor, the content of Ho substituted at the sites of Gd is limited and Ho is selected are now described.

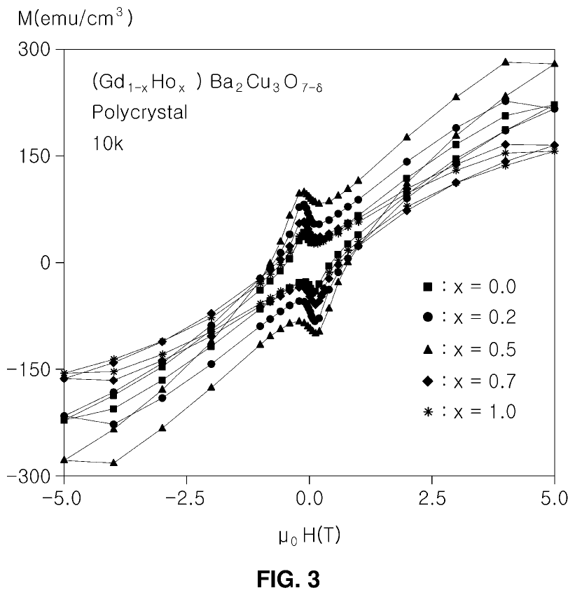

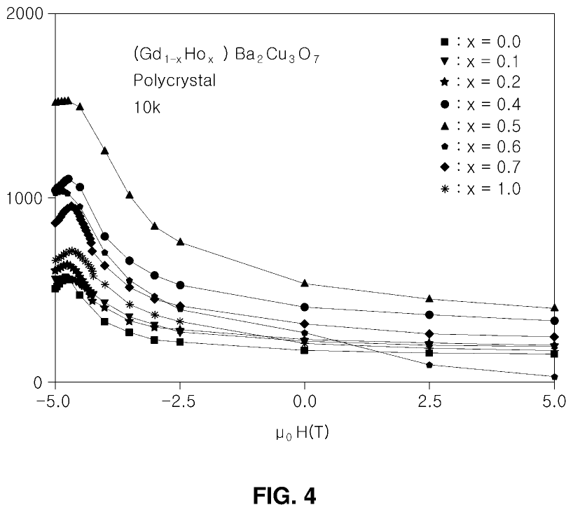

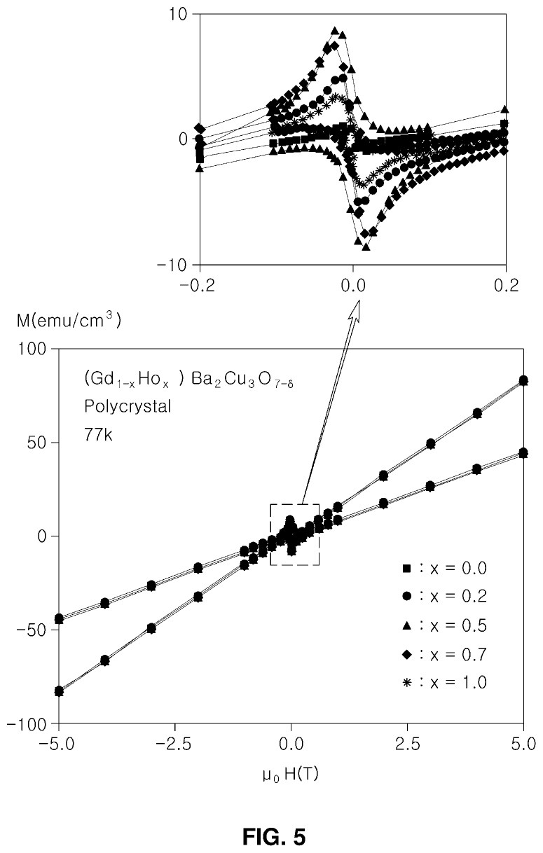

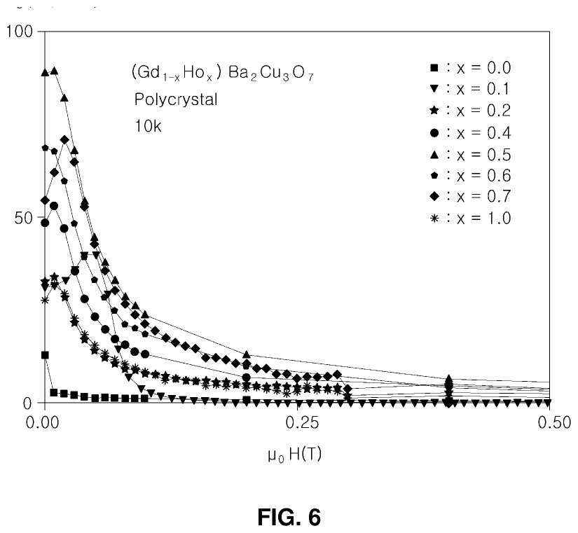

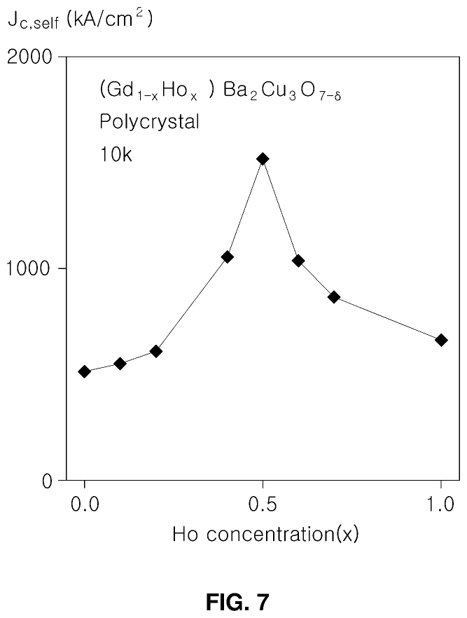

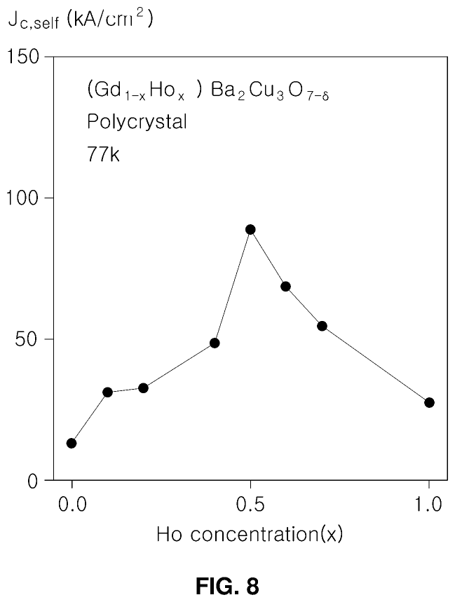

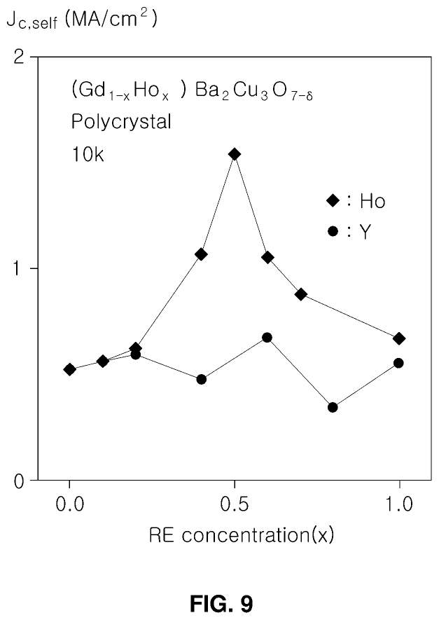

FIG. 3 depicts a graph showing a change in magnetic susceptibility as a function of the addition of Ho at 10 K; FIG. 4 depicts a graph showing a change in critical current density as a function of the addition of Ho at 10 K by using Bean model; FIG. 5 depicts a graph showing a change in magnetic susceptibility as a function of the addition of Ho at 77 K; FIG. 6 depicts a graph showing a change in critical current density as a function of the addition of Ho at 77 K by using Bean model; FIG. 7 depicts a graph showing a change in critical current value as a function of the addition of Ho at 10 K; FIG. 8 depicts a graph showing a change in critical current value as a function of the addition of Ho at 77 K; and FIG. 9 depicts a graph showing changes in critical current value as a function of the type of rare earth element substituted for Gd and the additional amount thereof.

In order to examine magnetic characteristics depending on the additional amount of Ho substituted at the sites of Gd in the superconductor, the magnetic susceptibility by an external magnetic field was measured under 10 K and 77 K conditions through a mechanical properties measurement system (MPMS). The results are show in FIGS. 3 and 5.

As the data in FIGS. 3 and 5 confirms, the magnetic susceptibility was increased with an increasing additional amount of Ho, but decreased when the additional amount of Ho exceeds 50%.

Particularly, it was confirmed that the magnetic susceptibility was significantly improved when the additional amount of Ho is about 40-60 mol %. The partial substitution of Gd with Ho may be considered to yield desired results.

In order to examine the change in the critical current value as a function of the additional amount of Ho substituted at the sites of Gd in the superconductor, the critical current density was calculated under 10 K and 77 K conditions by utilizing the Extended Beans critical current model.

The critical current density was calculated by insertion in the following expression, and the results are shown in FIGS. 4 and 6.

### <Critical Current Density Calculation Expression>

$${J}_{c} = \frac{20}{a ( 1 - \frac{a}{3 b} )} Δ M$$

In the expression for the critical current density calculation, ‘a’ represents the horizontal length of the measured sample, ‘b’ represents the vertical length, and ΔM signifies the difference in the y-axis values at the same magnetic field on the x-axis in the magnetization curve measured by MPMS (Magnetic Property Measurement System).

As the data in FIGS. 4 and 6 confirms, the critical current density value was increased with an increasing additional amount of Ho, but decreased when the additional amount of Ho exceeds 50%.

In particular, the data confirms that the critical current density value was significantly improved when the additional amount of Ho is about 40-60 mol %.

In order to examine a change in the critical current density as a function of the additional amount of Ho substituted at the sites of Gd in the superconductor, actual specimens were fabricated and measured for critical current density under 10 K and 77 K conditions. The results are shown in Table 1 and FIGS. 7 and 8.

TABLE 1

| Ho (mol %) | 0 | 10 | 20 | 40 | 50 | 60 | 70 | 100 |
|---|---|---|---|---|---|---|---|---|
| 77K (KA/cm²) | 14.18 | 32.91 | 33.71 | 53.21 | 88.74 | 75.14 | 61.86 | 31.10 |
| 10K (KA/cm²) | 516.26 | 586.44 | 610.42 | 1051.14 | 1511.68 | 1048.23 | 868.03 | 635.65 |

As the data in Table 1 and FIGS. 7 and 8 confirms, the critical current density was increased/decreased depending on the addition of Ho, and as the additional amount of Ho increased, the critical current density was also increased.

The critical current density showed a rapid increase when the additional amount of Ho was about 40-50%, and showed a rapid decrease when the additional amount of Ho exceeds 50%.

The data confirmed that the critical current density value could be adjusted by the addition of Ho, and the additional amount of Ho was about 40-60%, where the critical current density was higher than 1000 kA/cm² at 10 K and higher than 50 kA/cm₂ at 77 K.

Without being limited by theory, the reason why Ho was selected as a rare earth element substituting for Gd is now described.

According to one or more aspects of the present disclosure, there is provided a ReBCO-based high-temperature superconductor, which is represented by ReBa₂Cu₃O_{7-δ}, wherein Re is Gd and Ho.

The high-temperature superconductor is represented by HoₓGd₁₋ₓBa₂Cu₃O_{7-δ}, in which x satisfies 0<x<1 and δ satisfies δ<7.

In particular, x satisfies 0.4≤x≤0.6.

According to one or more aspects of the present disclosure, there is provided a (Gd,Ho)BCO-based high-temperature superconductor, wherein a part of Gd is substituted with Ho.

The amount of Ho substituted may be 40-60% of the mole percentage of Gd before substitution.

According to one or more aspects of the present disclosure, there is provided a method for preparing a (Gd,Ho)BCO-based superconductor, the method including: a powder preparation step of separately preparing a Gd oxide powder, a Ba oxide powder, a Cu oxide powder, and a Ho oxide powder; a mixing step of mixing the prepared Gd oxide powder, Ba oxide powder, and Cu oxide powder according to the stoichiometry to prepare a mixed powder while substituting a part of the Gd oxide powder with the Ho oxide powder; a molding step of molding the prepared mixture powder into a molded body; a first heat treatment step of adjusting the content of carbon (C) in the molded body; a second heat treatment step of synthesizing the molded body into a (Gd,Ho)BCO-based molded body; a third heat treatment step of growing crystal grains of the molded body; and an oxygen heat treatment step of adjusting the content of oxygen (O) in the molded body.

In the mixing step, the amount of Ho of the Ho oxide powder substituted with Gd of the Gd oxide powder may be 40-60% of the mole percentage of Gd.

In the molding step, the mixture powder is press-molded.

In the molding step, the mixture powder may be press-molded at 5-20 MPa.

The first heat treatment step includes: a first heating step of heating the molded body at a heating rate of 10° C./min or less; a first maintaining step of maintaining the molded body at 880° C. for 20 hours or longer; and a first cooling step of cooling the molded body at a cooling rate of 10° C./min or less.

The second heat treatment step includes: a second heating step of heating the molded body at a heating rate of 10° C./min or less; a second maintaining step of maintaining the molded body at 900° C. for 20 hours or longer; and a second cooling step of cooling the molded body at a cooling rate of 10° C./min or less.

The third heat treatment step includes: a third heating step of heating the molded body at a heating rate of 10° C./min or less; a third maintaining step of maintaining the molded body at 925° C. for 15 hours or longer; and a third cooling step of cooling the molded body at a cooling rate of 10° C./min or less.

In the oxygen heat treatment step, the molded body may be heat-treated at 500° C. for 12 hours or longer in an oxygen atmosphere.

FIG. 9 depicts a graph showing changes in critical current value as a function of the type of rare earth element substituted for Gd and the additional amount thereof.

In the present example, for a rare earth element to be substituted at the sites of Gd, an element of the Lanthanide group was selected by consideration of a similar ionic diameter to Gd and changes in the magnetic moment (pB/h) and the critical current density (A); The substitution with Ho was confirmed to be able to significantly increase the critical current density. The partial substitution of Gd with Ho may be considered to yield meaningful results Therefore, Ho, Tb, Y, and Lu of the Lanthanide group, which have similar ionic diameters to Gd, were separately substituted at the same proportion at the sites of Gd in the crystal structure of the unit lattice of the superconductor, and the magnetic moment and critical current density measured. The data are shown in Table 1.

In addition, the critical current density values were measured while the additional amounts of Ho and Y were varied; the results are shown in Table 2 and Table 9.

TABLE 2

| Classification | Gd³⁺ | Ho³⁺ | Tb³⁺ | Y³⁺ | Lu³⁺ |
|---|---|---|---|---|---|
| Ionic | 93.5 | 90.1 | 92.3 | 90 | 86.1 |
| diameter | | | | | |
| Magnetic | 6.9 | 10.6 | 9.3 | 0 | Diamagnetic |
| moment | | | | | |
| (μB/h) | | | | | |
| Critical | Standard | Increase | Impossible | No | Increase |
| current | | | to | difference | (about 2- |
| density (A) | | | preparation | | fold) |

As evidenced by the data in Table 2 and FIG. 9, among the elements of the Lanthanide group substituted at the sites of Gd, Ho was found to improve the magnetic moment and critical current density value of the high-temperature superconductor.

Although the present disclosure has been described and illustrated in conjunction with the accompanying drawings and exemplary embodiments thereof, the present disclosure is not limited thereto and is defined by the appended claims. Therefore, those skilled in the art may make various changes and modifications to the present disclosure without departing from the technical idea of the present disclosure defined by the appended claims.

What is claimed is:

1. A rare-earth barium copper oxide (ReBCO)-based high-temperature superconductor composition represented by ReBa₂Cu₃O_{7-δ}, wherein Re is Gd and Ho.

2. The high-temperature superconductor composition of claim 1, represented by HoₓGd₁₋ₓBa₂Cu₃O_{7-δ}, wherein x satisfies 0<x<1 and δ satisfies δ<7.

3. The high-temperature superconductor composition of claim 2, wherein x satisfies 0.4≤x≤0.6.

4. A (Gd,Ho)BCO-based high-temperature superconductor composition, wherein a part of Gd is substituted with Ho.

5. The high-temperature superconductor composition of claim 4, wherein about 40-60% of a mole percentage of Gd before substitution is substituted with Ho.

6. A method for preparing a (Gd,Ho)BCO-based superconductor composition, the method comprising:
preparing separately a Gd oxide powder, a Ba oxide powder, a Cu oxide powder, and a Ho oxide powder;
a mixing step comprising mixing the prepared Gd oxide powder, Ba oxide powder, and Cu oxide powder according to a stoichiometry to prepare a mixed powder wherein a part of the Gd oxide powder is substituted with the Ho oxide powder;
a molding step comprising molding the prepared mixture powder into a molded body;
a first heating step comprising adjusting an amount of carbon (C) in the molded body;
a second heating step comprising synthesizing the molded body into a (Gd,Ho)BCO-based molded body;
a third heating step comprising growing crystal grains of the molded body; and
an oxygen heating step comprising adjusting an amount of oxygen (O) in the molded body.

7. The method of claim 6, wherein in the mixing step, 40-60% of a mole percentage of Gd of the Gd oxide powder is substituted with Ho of the Ho oxide powder.

8. The method of claim 6, wherein in the molding step, the mixture powder is press-molded.

9. The method of claim 8, wherein in the molding step, the mixture powder is press-molded at about 5-20 MPa.

10. The method of claim 6, wherein the first heating step comprises:
heating the molded body at a heating rate between about 10° C./min and about 1° C./min;
maintaining the molded body at about 880° C. for at least about 20 hours; and
cooling the molded body at a cooling rate between about 10° C./min and about 1° C./min.

11. The method of claim 6, wherein the second heating step comprises:
heating the molded body at a heating rate between about 10° C./min and about 1° C./min;
maintaining the molded body at about 900° C. for at least about 20 hours; and
cooling the molded body at a cooling rate between about 10° C./min and about 1° C./min.

12. The method of claim 6, wherein the third heating step comprises:
heating the molded body at a heating rate between about 10° C./min and about 1° C./min;
maintaining the molded body at about 925° C. for at least about 15 hours; and
cooling the molded body at a cooling rate between about 10° C./min and about 1° C./min.

13. The method of claim 6, wherein in the oxygen heating step, the molded body is heat-treated at about 500° C. for at least about 12 hours in an oxygen atmosphere.
